(19) United States
(12) Patent Application Publication
(10) Pub. No.: US 2026/0271174 A1
(43) Pub. Date: Sep. 10, 2026

(54) PRINTED CIRCUIT BOARD ASSEMBLY

(71) Applicant: Rolls-Royce Deutschland Ltd & Co KG, Blankenfelde-Mahlow (DE)

(72) Inventors: Jan Magnus FARSTAD, Trøndheim (NO); Maria BOE, Trøndheim (NO); Niklas SCHAMBERGER, Blankenfelde-Mahlow (DE); Lukas SOBOTTA, Blankenfelde-Mahlow (DE)

(21) Appl. No.: 18/869,607

(22) PCT Filed: May 25, 2023
(86) PCT No.: PCT/EP2023/064112

§ 371 Date: Nov. 26, 2024

(30) Foreign Application Priority Data
May 31, 2022 (DE) 10 2022 113 633.7

(51) Int. Cl. H05K 1/02; H02M 7/00; H05K 1/14; H05K 1/181

(52) U.S. Cl. CPC H05K 1/0203; H02M 7/003; H05K 1/144; H05K 1/181; H05K 2201/042; H05K 2201/066; H05K 2201/10015; H05K 2201/10409

(57) ABSTRACT

A printed circuit board assembly includes: a first printed circuit board having an upper side and a lower side; at least one electrical component to be cooled arranged on the lower side of the first printed circuit board; and a heat sink arranged underneath the first printed circuit board, which is configured to cool the at least one component. The printed circuit board further includes a hold-down device connected to the first printed circuit board, which is configured to exert pressure on the upper side of the first printed circuit board. The hold-down device has a fastening mechanism configured to fasten a second printed circuit board that extends parallel to the first printed circuit board, wherein the hold-down device is arranged between the first printed circuit board and the second printed circuit board.

The present patent document is a § 371 nationalization of PCT Application Ser. No. PCT/EP2023/064112, filed May 25, 2023, designating the United States, and this patent document also claims the benefit of German Patent Application No. 10 2022 113 633.7, filed May 31, 2022, which are incorporated by reference in their entireties.

### TECHNICAL FIELD

The disclosure relates to a circuit board assembly.

### BACKGROUND

The prior art includes the practice of cooling circuit board-based power electronics assemblies by pressing them against a heat sink by screwed joints, wherein the components to be cooled may be configured as surface-mounted (SMD) components (“surface-mounted device”) or as through-hole assemblies (THT=“through-hole technology”) and are seated on the underside of a circuit board.

In this case, a gap between the component to be cooled and the heat sink, which would lead to impairment of the thermal connection of the electrical component to the heat sink, must be minimized. In the case of a plurality of components that need to be cooled, there may be gaps with different gap dimensions with respect to the heat sink, which need to be compensated.

A good thermal connection is required to press the components to be cooled against the heat sink. A certain amount of contact pressure is required to provide full-surface contact between the component to be cooled and the heat sink, in particular to compensate for unevenness and tilting. Accordingly, it makes sense to realize a large number of screw connections that press the components to be cooled against the heat sink. On the other hand, a large number of screw connections goes hand in hand with a large number of holes in the circuit boards, which is complex in terms of production technology and restricts the options for routing the conductor tracks and arranging the components.

### SUMMARY AND DESCRIPTION

The object of the present disclosure is to provide a circuit board assembly that enables the thermal connection of a component to be cooled to a heat sink in an effective manner and additionally enables an effective structure of the circuit board assembly.

The scope of the present disclosure is defined solely by the appended claims and is not affected to any degree by the statements within this summary. The present embodiments may obviate one or more of the drawbacks or limitations in the related art.

The disclosure provides a circuit board assembly that has a first circuit board with an upper side and an underside, at least one electrical component to be cooled arranged on the underside of the first circuit board, and a heat sink arranged below the first circuit board, wherein the heat sink is configured to cool the at least one component to be cooled.

A hold-down device is provided here, which is connected to the first circuit board and which is configured to exert pressure on the upper side of the first circuit board, wherein the hold-down device has a fastening mechanism for fastening a second circuit board that extends parallel to the first circuit board, and wherein the hold-down device is arranged between the first circuit board and the second circuit board.

The solution according to the disclosure includes using a hold-down device that, by exerting pressure on the upper side of the first circuit board, presses the first circuit board or the electrical components arranged on the underside of the first circuit board against the heat sink. The use of a hold-down device provides additional rigidity in particular, as the hold-down device prevents or reduces upward curvature of the circuit board when the electrical components arranged on the underside of the circuit board are pressed against the heat sink. In this way, uniform pressure is applied to the circuit board, at least in the region in which the components to be cooled are arranged, so that the components to be cooled are also pressed evenly against the heat sink. This provides a good thermal connection between the components to be cooled and the heat sink and therefore effective cooling.

The additional rigidity also makes it possible to reduce the number of screw connections to be used and/or to provide such connections only in edge regions, thus reducing the manufacturing effort. At the same time, the reduced number of holes in the circuit board increases design freedom when arranging the conductor tracks and components.

A further advantage associated with the disclosure is that, by integrating a fastening mechanism for fastening a second circuit board in the hold-down device, fastening structures are provided that make it possible to realize the second circuit board at the desired spacing in the circuit board assembly. This means that no additional measures are required, such as attaching fastening points and/or spacer sleeves to the first circuit board in order to define the desired distance between the two circuit boards.

Lastly, the present disclosure also makes it possible to cool electrical components arranged on the underside of the second circuit board. Such electrical components cannot be cooled by the heat sink. If the hold-down device is made of metal, the hold-down device may take on the function of absorbing heat from electrical components on the second circuit board and spreading it thermally within the plane of the hold-down device in the surface. In this respect, the hold-down device serves as a heat sink for components to be cooled on the second circuit board. Components may be arranged on the second circuit board that have a lower power loss compared to the components cooled by the heat sink on the first circuit board, so that cooling by the hold-down device is sufficient.

As disclosed herein, the side of the circuit board on which an electrical component to be cooled is arranged and adjoins a heat sink is referred to as the underside of the circuit board. This may be the side of the circuit board that is closer to the ground with respect to the vertical perpendicular direction. However, the circuit board and heat sink to be cooled may also be arranged in an inverted or vertical manner and accordingly point upwards or to the side, in which case the circuit board likewise adjoins the heat sink with its underside.

One embodiment of the disclosure provides that the hold-down device is arranged at a distance from the first circuit board and is connected to the first circuit board only at certain points (e.g., in a local region), wherein the hold-down device forms projections on its underside that project in the direction of the upper side of the first circuit board, bear against the latter and exert pressure on it. The projections projecting towards the upper side of the first circuit board provide that uniform pressure is exerted on the upper side of the first circuit board and that it cannot deform or bulge locally.

In particular, the projections are formed in such regions of the hold-down device that are adjacent to regions of the circuit board in which the first circuit board has electrical components to be cooled which are pressed against the heat sink. This is because the risk of the circuit board bulging is particularly high in such regions.

In a further embodiment, a heat-conducting material is arranged between the hold-down device and the first circuit board. This makes it possible to use the hold-down device to cool electrical components that are arranged on the upper side of the first circuit board.

A heat-conducting material, within the meaning of the present disclosure, may be a heat-conducting paste or a heat-conducting mat. Such a heat-conducting material is also known as a thermal interface material (TIM). Heat-conducting materials are used to thermally bridge a gap between various components, for example an electrical component to be cooled and the surface of a heat sink.

In a further embodiment, the hold-down device may be arranged at a distance from the second circuit board and connected to the second circuit board only at certain points, wherein the hold-down device forms projections on its upper side, which projections project in the direction of the underside of the second circuit board and bear against the latter. This prevents the second circuit board from curving and provides that the second circuit board rests evenly on the hold-down device.

In certain examples, a heat-conducting material is arranged between the hold-down device and the second circuit board. This further improves or effectively provides the described effect that the hold-down device acts as a heat sink for electrical components connected to the second circuit board. The heat-conducting material is again, for example, a heat-conducting paste or a heat-conducting mat.

In a further embodiment, the fastening mechanism of the hold-down device, which serves to fasten the second circuit board, includes holes in the form of threaded holes or simple holes. Threaded holes are used to accommodate fastening screws, which are used to connect the second circuit board to the hold-down device. Simple holes (without thread) are used to feed fastening screws through the hold-down device, wherein such screws are then screwed to a housing structure, for example.

The threaded holes may be at least partially formed in the projections on the upper side of the hold-down device. The holes may be formed in spacer sleeves of the hold-down device, which extend both in the direction of the first circuit board and in the direction of the second circuit board and define a distance between the hold-down device and the two circuit boards. In this variant, the spacer sleeves and the holes formed in them are used to accommodate threaded screws that extend into a housing structure.

Thus, a further embodiment of the disclosure provides that the circuit board is fastened to a housing structure that forms the heat sink or accommodates the heat sink. In the second case, for example, it is envisaged that the housing structure forms a cavity, and the heat sink is arranged in the cavity of the housing structure.

A further embodiment provides first fastening screws extending from the upper side of the second circuit board through the hold-down device and through the first circuit board into the housing structure and connecting the second circuit board, the hold-down device, and the first circuit board to the housing structure. The first fastening screws are thus screwed into the housing structure and connect the second circuit board, the hold-down device, and the first circuit board.

It is possible that the first fastening screws are only arranged in the edge region of the first circuit board. The first fastening screws may extend through the fastening mechanism of the hold-down device, which are configured as holes.

Alternatively, or in addition to the first fastening screws, a further embodiment provides for second fastening screws that extend from the upper side of the hold-down device through the first circuit board into the heat sink. The second fastening screws are thus screwed into the heat sink and connect the hold-down device and the first circuit board.

As an alternative or in addition to the first and/or second fastening screws, a further embodiment provides for third fastening screws that extend from the upper side of the second circuit board into the hold-down device and are screwed to the hold-down device via threaded holes. The threaded holes form the fastening mechanism for fastening the second circuit board. The third fastening screws are thus screwed to the hold-down device and connect the second circuit board to the hold-down device.

The hold-down device is formed, for example, as a rigid plate or rigid frame of a defined height and has a higher rigidity than the first circuit board and the second circuit board. These projections project upwards or downwards from the hold-down device and define its distance from the two circuit boards.

In certain embodiments, the hold-down device includes a metal or a metal alloy, (e.g., aluminum or an aluminum alloy). This is particularly the case if the hold-down device serves as a heat sink for electrical components that are connected to the second circuit board. In another embodiment, the hold-down device is configured as a plastic-metal hybrid. For example, a metal core is provided that is overmolded with a plastic. Insulation problems may be avoided with a hybrid design.

In further embodiments, a ceramic material is provided as the material of the hold-down device. A ceramic material has the advantage of high electrical insulation properties. Another advantage is greater rigidity compared to polymers and metals. However, this may result in poorer thermal properties compared to metals.

In a further embodiment, the at least one electrical component to be cooled is thermally coupled to the heat sink via a heat conducting material. The heat-conducting material thermally bridges a gap between the underside of the electrical component to be cooled and the surface of the heat sink. Such gaps result, for example, from tilting during assembly. In principle, however, it is also possible to press the electrical component to be cooled directly onto the heat sink.

The present disclosure may be suitable for cooling any electrical components that are connected to a circuit board. The electrical components may be assemblies such as pre-package modules with integrated electrical components and SMD contacts or THT contacts as well as individual electrical components.

Embodiments provide that the electrical components to be cooled are components or assemblies of the power electronics, in particular electrical components that interact to control and operate an electric motor. For example, the at least one electrical component to be cooled is an element of a converter for an electric motor.

In principle, the heat sink used may be configured in any way. The heat sink may include cooling fins. The heat sink may be an actively cooled heat sink or a passively cooled heat sink.

### BRIEF DESCRIPTION OF THE DRAWINGS

The disclosure is explained in greater detail below by a plurality of embodiments and with reference to the figures.

FIG. 1 depicts an embodiment of a circuit board assembly including two circuit boards and a hold-down device, wherein the hold-down device presses down one circuit board and has fastening mechanism for fastening the other circuit board.

FIG. 2 depicts an example of a circuit board assembly according to FIG. 1, wherein additional heat-conducting materials are arranged between the hold-down device and the two circuit boards.

### DETAILED DESCRIPTION

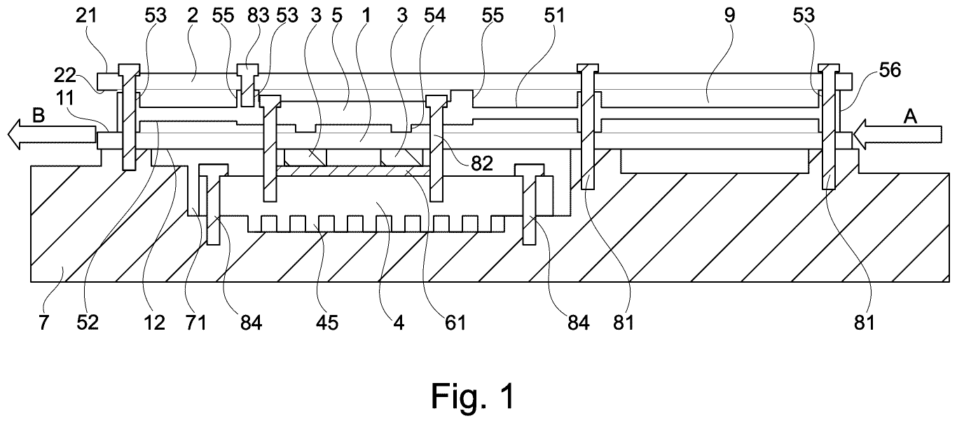

FIG. 1 shows an embodiment of a circuit board assembly in accordance with the present disclosure. The circuit board assembly has a first circuit board 1 and a second circuit board 2, which are arranged at a distance from each other and run parallel. Both circuit boards 1, 2 have an upper side 11, 21 and an underside 12, 22.

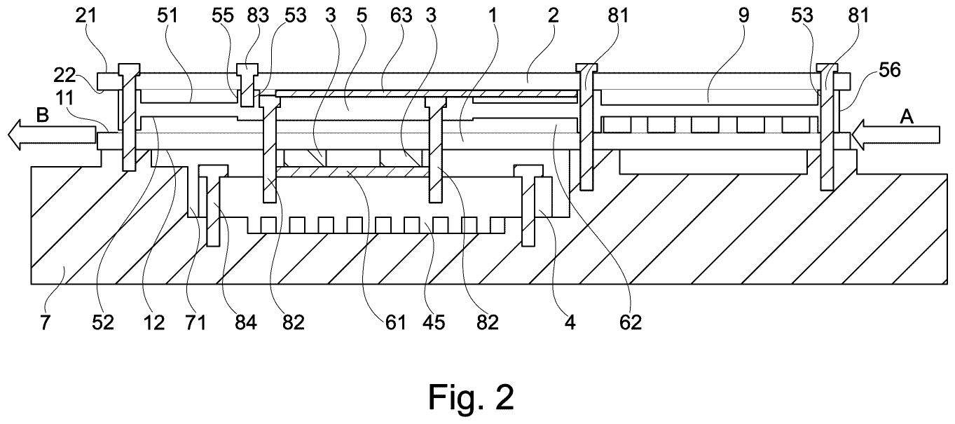

The first circuit board 1 has on its underside 12 one or more electrical components 3 that are to be cooled. FIG. 2 shows two such components 3, wherein this is only to be understood as an example. For example, a large number of electrical components 3 may be arranged in two or more rows on the underside 12 of the first circuit board 1. The electrical components 3 are, for example, components of power electronics, such as elements of a converter. The electronic components 3 may be configured as pre-package modules.

In one embodiment, the electrical components 3 are three power semiconductors of a converter, which is formed by the electronic components 3 and further components arranged on the circuit board 1. Such further components are only partially shown in FIG. 1. The other components include, for example, capacitors 9, which are arranged on the upper side 11 of the circuit board 1. The converter realized on the circuit board 1 receives a DC voltage on the input side (shown schematically by arrow A) and outputs an AC voltage on the output side (shown schematically by case B).

The connection of the electrical components 3 to the circuit board 1 is made, for example, via surface mounting, wherein the components 3 are SMD components. This is however to be understood merely as an example.

The electrical components 3 are configured to be cooled by a heat sink 4. For this purpose, the underside of the electrical components 3 is pressed against the heat sink 4 with a pressure that creates full-surface contact with the heat sink 4. The heat sink 4 may have numerous configurations. For example, the heat sink 4 is made of a metal such as, for example, aluminum or an aluminum alloy and has cooling surfaces 45. The heat sink 3 is, for example, an active heat sink, which is actively cooled by a fan (not shown) or by a liquid cooling system (not shown). Alternatively, the heat sink 4 is configured as a passive heat sink.

The heat sink 4 is arranged in a cavity 71 of a housing structure 7, which is, for example, a motor housing of an electric motor. In alternative embodiments, the housing structure 7 may form the heat sink, wherein no separate heat sink 4 is provided. In this case, the electrical components 3 to be cooled are pressed against a surface of the housing structure 7.

The respective electrical component 3 is connected to the heat sink 4 via a heat-conducting material 61. The heat-conducting material 61 is formed, for example, by a heat-conducting paste or a heat-conducting mat and thermally couples the electrical component 3 to the heat sink 4. In doing so, the heat-conducting material 61 bridges a gap that may extend between the underside of the electrical component 3 and the surface of the heat sink 4 without such a heat-conducting material 61.

A hold-down device 5 extends between the first circuit board 1 and the second circuit board 2 and has an upper side 51 and an underside 52 and is formed by a flat structure. The hold-down device 5 is made of a metal or a metal alloy such as aluminum or an aluminum alloy and is more rigid than the circuit boards 1, 2. The hold-down device 5 is configured as a plate with a defined height or thickness. The hold-down device 5 fulfills two functions. On the one hand, the hold-down device 5 exerts pressure on the upper side 11 of the first circuit board 1. On the other hand, the hold-down device 5 is used to fasten the second circuit board 2.

In order to exert pressure on the upper side 11 of the circuit board 1, the hold-down device 5 includes projections 54 on its underside 52, which project in the direction of the first circuit board 1 and rest against the latter. Due to the greater rigidity of the hold-down device 5, it prevents the circuit board 11 from curving, which may occur when the circuit board 1 with the components 3 to be cooled is pressed against the heat sink 4. A homogeneous pressure is provided with which the electrical components 3 are pressed against the heat sink 4.

The projections 54 are formed in the hold-down device 5 in such a way that their position corresponds in each case to the position of an electrical component 3 to be cooled, so that uniform pressure of an electrical component 3 against the heat sink 4 is provided via the projections 54 in each case.

To provide a fastening of the second circuit board 2 to the hold-down device 5, the hold-down device 5 includes a fastening mechanism. The fastening mechanism is in any case partly formed by threaded holes. Thus, the hold-down device 5 includes threaded holes 53, which serve to receive fastening screws 83, which extend from the upper side 21 of the second circuit board 2 into the hold-down device 5. The threaded holes 53 are formed, for example, in projections 55 which extend from the upper side 51 of the hold-down device 5 in the direction of the second circuit board 2 and rest against its underside 22. The projections 55 are also used to precisely position and define the distance of the second circuit board 2 from the hold-down device 5.

The hold-down device 5 also forms spacer sleeves 56, in which an upwardly projecting projection and a downwardly projecting projection merge directly into one another and have a common hole 53. These holes 53, which may be configured as simple holes or as threaded holes, serve to receive further fastening screws 81, which extend from the upper side 21 of the second circuit board 2 through the hold-down device 5 (namely the spacer sleeve 56) and the first circuit board 1 into the housing structure 7 and are screwed into the latter. The two circuit boards 1, 2 and the hold-down device 5 are fastened to the housing structure 7 using the fastening screws 81. The fastening screws 81 are only arranged in the edge region of the circuit boards 1, 2 and the hold-down device 5.

As shown in FIG. 1, the circuit board assembly further includes fastening screws 82, which extend from the upper side 51 of the hold-down device 5 through the first circuit board 1 into the heat sink 4 and are screwed into the latter. The fastening screws 82 provide the compressive force with which the electrical components 3 to be cooled are pressed against the heat sink 4. Because this function is also provided by the hold-down device 5 and its projections 54, it is possible to reduce the number of fastening screws 82 or even dispense with them altogether, which is associated with the advantage, among other things, that fewer drill holes have to be formed in the first circuit board 1, so that there are fewer restrictions on the placement of components on the circuit board 1 and the routing of the conductor tracks.

Furthermore, fastening screws 84 are provided to screw the heat sink 4 to the housing structure 7.

The respective fastening screws 81-84 are configured as metal screws, for example.

FIG. 2 shows an embodiment of a circuit board assembly that corresponds to the construction of the circuit board assembly in FIG. 1, and therefore reference is made to the statements in this regard. In FIG. 2, two additional heat-conducting materials 62, 63 are provided, which extend between the hold-down device 5 and the first circuit board 1 and between the hold-down device 5 and the second circuit board 2. The use of such heat-conducting materials 62, 63 means that the metal hold-down device 5 may act as an additional heat sink. This applies in particular to electrical components that are arranged on the second circuit board 2 (not shown separately) and that require less cooling than the electrical components 3 which are cooled by the heat sink 4. This also applies to electrical components arranged on the upper side of the first circuit board 1 (not shown separately).

The projections 54 shown in FIG. 1, which extend in the direction of the first circuit board 1, are not visible in FIG. 2 due to the representation of the heat conductor material 62, but are also present. The same applies to the upwardly projecting projections 55, which are only partially shown in FIG. 2.

The circuit boards 1, 2 and their components are shown in FIG. 1 only schematically and only insofar as it is relevant to the present disclosure. In particular, the circuit boards 1, 2 may have further components, not shown (on the upper side and/or the underside). The structure and contacting of the circuit boards are also not shown separately. The circuit boards 1, 2 may include a plurality of circuit board layers.

It should be understood that the disclosure is not limited to the above-described embodiments and different modifications and improvements may be carried out without deviating from the concepts described here. For example, the circuit board arrangement may have additional circuit boards and components mounted on them.

It should further be noted that any of the described features may be used separately or in combination with any other features, provided that they are not mutually exclusive. The disclosure extends to and includes all combinations and sub-combinations of one or more features which are described here and includes these. If ranges are defined, these ranges therefore include all the values within these ranges as well as all the partial ranges that lie within a range.

1. A circuit board assembly, comprising:
a first circuit board having an upper side and an underside;
at least one electrical component to be cooled arranged on the underside of the first circuit board;
a heat sink arranged underneath the first circuit board, wherein the heat sink is configured to cool the at least one electrical component; and
a hold-down device connected to the first circuit board, wherein the hold-down device is configured to exert pressure on the upper side of the first circuit board,
wherein the hold-down device comprises a fastening mechanism configured to fasten a second circuit board that extends parallel to the first circuit board, and
wherein the hold-down device is arranged between the first circuit board and the second circuit board.

2. The circuit board assembly of claim 1, wherein the hold-down device is arranged at a distance from the first circuit board and is connected to the first circuit board only at certain points,
wherein the hold-down device forms projections on an underside of the hold-down device, and
wherein the projections project in a direction of the upper side of the first circuit board and bear against the upper side of the first circuit board.

3. The circuit board assembly of claim 2, wherein the projections are formed in such regions of the hold-down device that are adjacent to regions of the first circuit board in which the first circuit board has the at least one electrical component to be cooled pressed against the heat sink.

4. The circuit board assembly of claim 1, further comprising:
a heat-conducting material arranged between the hold-down device and the first circuit board.

5. The circuit board assembly of claim 1, wherein the hold-down device is arranged at a distance from the second circuit board and is connected to the second circuit board only at certain points,
wherein the hold-down device forms projections on an upper side of the hold-down device, and
wherein the projections project in a direction of an underside of the second circuit board and bear against the second circuit board.

6. The circuit board assembly of claim 1, further comprising:
a heat-conducting material arranged between the hold-down device and the second circuit board.

7. The circuit board assembly of claim 1, wherein the fastening mechanism of the hold-down device, which is configured to fasten the second circuit board, comprises holes in a form of threaded holes or simple holes.

8. The circuit board assembly of claim 7,
wherein the hold-down device is arranged at a distance from the second circuit board and is connected to the second circuit board only at certain points,
wherein the hold-down device forms projections on an upper side of the hold-down device,
wherein the projections project in a direction of an underside of the second circuit board and bear against the second circuit board, and
wherein the threaded holes are formed at least partially in the projections formed on the upper side of the hold-down device.

9. The circuit board assembly of claim 7, wherein the holes are formed in spacer sleeves of the hold-down device, which extend both in a direction of the first circuit board and in a direction of the second circuit board and define a distance between the hold-down device and the first and second circuit boards.

10. The circuit board assembly of claim 1, wherein the first circuit board is fastened to a housing structure that forms the heat sink or accommodates the heat sink.

11. The circuit board assembly of claim 10, wherein the heat sink is arranged in a cavity of the housing structure.

12. The circuit board assembly of claim 10, further comprising:
fastening screws extending from the upper side of the second circuit board through the hold-down device and through the first circuit board into the housing structure,
wherein the fastening screws connect the second circuit board, the hold-down device, and the first circuit board to the housing structure.

13. The circuit board assembly of claim 12, wherein the fastening screws are arranged in an edge region of the first circuit board.

14. The circuit board assembly of claim 12,
wherein the fastening mechanism of the hold-down device comprises holes, and
wherein the fastening screws extend through the holes of the hold-down device.

15. The circuit board assembly of claim 1, further comprising:
fastening screws extending from an upper side of the hold-down device through the first circuit board into the heat sink.

16. The circuit board assembly of claim 7, further comprising:
fastening screws that extend from the upper side of the second circuit board into the hold-down device,
wherein the fastening screws are screwed to the hold-down device through the threaded holes.

17. The circuit board assembly of claim 1, wherein the hold-down device is a rigid plate or a rigid frame and has a higher rigidity than a rigidity of the first circuit board and a rigidity of the second circuit board.

18. The circuit board assembly of claim 1, wherein the hold-down device is formed from metal, metal alloy, or a plastic-metal hybrid.

19. The circuit board assembly of claim 1, wherein the at least one electrical component to be cooled is thermally coupled to the heat sink via a heat-conducting material.

20. The circuit board assembly of claim 1, wherein the at least one electrical component to be cooled is an element of a converter for an electric motor.
